(19) United States
(12) Patent Application Publication
(10) Pub. No.: US 2007/0037298 A1
(43) Pub. Date: Feb. 15, 2007

(54) Semiconductor device with ferroelectric capacitor and fabrication method thereof

(75) Inventors: Katsuyoshi Matsuura, Kawasaki (JP); Mitsushi Fujiki, Kawasaki (JP); Hiroyuki Mitsui, Suwa-shi (JP); Hiroaki Tamura, Suwa-shi (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignees: FUJITSU LIMITED, Kawasaki (JP); Seiko Epson Corporation, Tokyo (JP)

(21) Appl. No.: 11/407,921

(22) Filed: Apr. 21, 2006

(30) Foreign Application Priority Data
Aug. 15, 2005 (JP) 2005-235402

(51) Int. Cl. H01L 21/00

(52) U.S. Cl. 438/3

(57) ABSTRACT

A semiconductor device fabrication method includes the steps of forming a conductive plug in an insulating film so as to be connected to an element on a semiconductor substrate; forming a titanium aluminum nitride (TiAlN) oxygen barrier film over the conductive plug; forming a titanium (Ti) seed film over the oxygen barrier film; and forming a lower electrode film of a ferroelectric capacitor over the titanium seed film.

### CROSS-REFERENCE TO RELATED APPLICATIONS

This application is based upon and claims priority of Japanese Patent Application No. 2005-235402, filed in Aug. 15, 2005, the contents being incorporated herein by reference.

### BACKGROUND OF THE INVENTION

1. Field of the Invention

The present invention relates to a semiconductor device with a ferroelectric capacitor and a fabrication method thereof.

2. Description of the Related Art

Flash memory and ferroelectric RAM (FeRAM) are known as a nonvolatile memory that does not loose its data even if the system or the device is turned off. In other words, it is unnecessary for nonvolatile memories to have their memory contents periodically refreshed.

Flash memory has a floating gate embedded in the gate insulating film of an insulated gate field effect transistor (IGFET). To store information, an electric charge representing the information is accumulated in the floating gate. It is necessary to supply a tunneling current in order to write or erase the information, and a relatively high voltage has to be applied.

FeRAM stores information making use of the hysteresis characteristic of a ferroelectric material. A ferroelectric capacitor has a ferroelectric film inserted between a pair of electrodes. Upon application of an electric voltage between the electrodes, polarization occurs. Even after removing the applied electric voltage, spontaneous polarization is maintained. When inverting the polarity of the applied voltage, the spontaneous polarization is also inverted. By detecting the spontaneous polarization, information can be read from the memory. FeRAM can operate at a lower voltage, and is capable of high-speed writing operations, while saving electric power, as compared with flash memories.

FIG. 1A and FIG. 1B are circuit diagrams of an FeRAM memory cell. FIG. 1A illustrates a 2T/2C FeRAM using two transistors (Ta and Tb) and two capacitors (Ca and Cb) to store 1-bit information. One of the capacitors (e.g., Ca) stores “1” or “0”, and the other capacitor (e.g., Cb) stores the inverted information to carry out complimentary operations. This configuration is durable against process fluctuation, but requires double the cell area, as compared with 1T/1C FeRAM.

FIG. 1B illustrates a 1T/1C FeRAM using a transistor (T1 or T2) and a capacitor (C1 or C2) to store 1-bit information. This configuration is the same as a DRAM structure, and suitable for high-density integration because of a smaller cell area. However, a reference voltage is required to determine whether the electric charge read from the memory cell represents “1” or “0”. Because the reference cell for generating the reference voltage has to invert the polarization every time information is read from the memory cell, it is degraded much earlier than the memory cell due to fatigue. In addition, the determination margin of the 1T/1C cell is narrower than that of a 2T/2C cell, and it is weak in process fluctuation.

The ferroelectric film used in a FeRAM is made of a PZT based material, such as lead-zirconium-titanium oxide (PZT) or La-doped PZT (PLZT), or a bismuth (Bi) layered compound, such as SrBi₂Ta₂O₉ (SBT, Yl) or SrBi₂(Ta, Nb)₂O₉ (SBTN, YZ). Ferroelectric materials easily suffer from hydrogen reduction. In order to maintain the FeRAM quality, recovery annealing is performed on the ferroelectric film at 500° C. to 700° C. in the oxidizing atmosphere because the subsequent process after formation of the ferroelectric capacitor includes hydrogen generating steps including growth of interlevel dielectric films.

The next-generation FeRAM, such as 0.18 μm FeRAM, will obviously employ the 1T/1C structure, and is supposed to employ a stacked capacitor structure (for directing connecting the ferroelectric capacitor to the transistor using a plug electrode) for the purpose of further increasing the degree of integration.

Plug electrodes are typically formed of tungsten (W) because tungsten is a low-resistance and heat-stable material, as compared with doped silicon. However, when oxidized, tungsten forms a high-resistance oxide. Only partial oxidation of the tungsten plug causes the plug resistance to greatly increase, which makes it difficult to ensure electric contact and prevents the FeRAM from correctly functioning as a memory device.

Meanwhile, because of the recovery annealing performed in the oxidizing atmosphere, a noble metal such as platinum (Pt) or iridium (Ir), or a material that can maintain electric conductivity even under the oxidizing environment, such as IrO₂, SrRuO₃, or La_{0.5}Sr_{0.5}CoO₃, is used to form the lower electrode of the ferroelectric capacitor. However, the lower electrode made of the above-described material cannot prevent oxygen diffusion at or near 600° C. This means that the recovery annealing performed at a high temperature (at or above 600° C.) causes the tungsten plug to be oxidized through the lower electrode.

To prevent such interface oxidation, it is proposed to insert an oxygen barrier film between the lower electrode and the plug electrode (See, for example, Japanese Patent Application Laid-open Publication No. 8-64786). This publication disclose that by using titanium aluminum nitride (TiAlN) as the oxygen barrier film, a capacitor can be fabricated using a high dielectric constant material without oxidizing the plug electrode because the oxidation rate of TiAlN is smaller than that of TiN by two orders of magnitude or more. Although aluminum nitride (AlN) is an insulator, impurity-added AlN is a conductor. Impurities can be added to AlN by causing a nitrogen (N) lacking state or adding a cationic impurity, such as titanium (Ti) ions.

By the way, the ferroelectric film is formed generally by sputtering; however, a sol-gel method or an MOCVD method is also used to form the ferroelectric film. When a ferroelectric film, such as a PZT film, is formed by a sputtering method, the lower electrode positioned under the ferroelectric film is formed of platinum (Pt). This is because the underlying lower electrode has to be a (111) oriented film in order to increase the spontaneous polarization of the PZT crystal, and because platinum (Pt) is strongly (111) oriented and suitable for the lower electrode.

With a sputtering method, if a PZT film is grown at a high temperature, the crystal quality is degraded. For this reason, an amorphous film is formed at a low temperature, and then rapid thermal annealing (RTA) is performed in the oxygen atmosphere to crystallize the film. Since RTA crystallization requires a high temperature at or above 700° C., the tungsten (W) plug is likely to be oxidized even if an oxygen barrier film (such as a TiAlN film) is used.

In contrast, metal organic chemical vapor deposition (MOCVD) techniques allow a PZT film to maintain good crystal quality during growth on the lower electrode, and do not require crystallization annealing. Accordingly, the process temperature can be reduced. However, if the PZT film is formed by MOCVD on a platinum (Pt) lower electrode, the lead (Pb) contained in the PZT film reacts with platinum to produce PtPbₓ, which reaction product damages the interface between the lower electrode and the PZT film and degrades the film qualities. Accordingly, when the PZT film is formed by MOCVD, platinum (Pt) cannot be used as the lower electrode material.

It is proposed to use a material other than platinum (Pt) for the lower electrode when employing an MOCVD method to form a ferroelectric film. Such a material includes a noble metal except for Pt, and a conductive noble metal oxide. Among these materials, oxide conductors, such as iridium oxide (IrOₓ), are unsuitable for the lower electrode because the oxide conductors are subjected to reduction during the MOCVD process for forming the PZT film.

For this reason, a noble metal that is nonreactive with PZT (e.g., iridium) is used as the lower electrode material. In addition, inserting the TiAlN oxygen barrier film between the Ir electrode and the W plug is advantageous from the viewpoint of oxidation resistance because the electric contact property of the tungsten (W) plug can be maintained even if recovery annealing is performed at or above 700° C.

However, through thorough research, it is found that the crystal quality of the iridium (Ir) film formed on the titanium aluminum nitride (TiAlN) is unsatisfactory. This is because the crystal quality of the TiAlN film itself is degraded, and because the degraded crystal quality of the TiAlN film causes the crystal quality of the iridium (Ir) film to be also degraded. The crystal degradation of the lower electrode further degrades the crystal quality of the ferroelectric film, and as a result, satisfactory FeRAM functions cannot be brought out.

### SUMMARY OF THE INVENTION

The present invention is conceived in view of the above-described problems in the prior art, and it is an object of the invention to improve the crystal quality of iridium (Ir) used in the lower electrode even if a TiAlN barrier film superior in oxidation resistance is used in a stacked capacitor FeRAM, and to maintain good crystal quality of a ferroelectric film. In other words, an embodiment of the invention provides a semiconductor device with a reliable ferroelectric film and a fabrication method thereof.

In an embodiment, titanium (Ti) film with strong self-orientation is formed as a seed film on titanium aluminum nitride (TiAlN) film prior to forming an iridium (Ir) film. This arrangement can improve the crystal quality of the iridium film, and accordingly, improve the crystal quality of the ferroelectric film formed on the iridium film.

In one aspect of the invention, a semiconductor device with a ferroelectric capacitor is provided. In this semiconductor device, the lower electrode of the ferroelectric capacitor is provided over a titanium aluminum nitride (TiAlN) film via a titanium (Ti) film inserted between the lower electrode and the TiAlN film. The titanium aluminum nitride (TiAlN) film is positioned directly on a conductive plug for electrically connecting the ferroelectric capacitor to an element formed over a semiconductor substrate.

In another aspect of the invention, a semiconductor device fabrication method is provided. The method comprises the steps of:

(a) forming a conductive plug in an insulating film on a semiconductor substrate so as to be connected to an element on the semiconductor substrate;

(b) forming a titanium aluminum nitride barrier film over the conductive plug;

(c) forming a titanium seed film on the titanium aluminum nitride barrier film; and

(d) forming a lower electrode of a ferroelectric capacitor.

The above-described structure and method can improve the crystal quality of the lower electrode, and therefore improve the polarization characteristic of the ferroelectric film, while efficiently preventing oxidation of the conductive plug for electrically connecting the ferroelectric capacitor to the element on the semiconductor.

Because the crystal quality of the ferroelectric film is improved and oxidation of the contact plug is prevented, reliable electric contact with the element on the semiconductor substrate can be ensured, while maintaining a high switching capacitance (Qsw). Consequently, a stacked ferroelectric capacitor with high reliability is realized.

### BRIEF DESCRIPTION OF THE DRAWINGS

Other objects, features, and advantages of the present invention will become more apparent from the following detailed description when read in conjunction with the accompanying drawings, in which:

FIG. 1A and FIG. 1B illustrate memory cell circuits of a 2T/2C FeRAM and a 1T/1C FeRAM, respectively;

FIG. 2A through FIG. 2G illustrate a semiconductor device fabrication process according to an embodiment of the invention; and

FIG. 3A and FIG. 3B are graphs showing XRD rocking curves of iridium layers formed by the conventional method and a new method according to an embodiment of the invention, respectively.

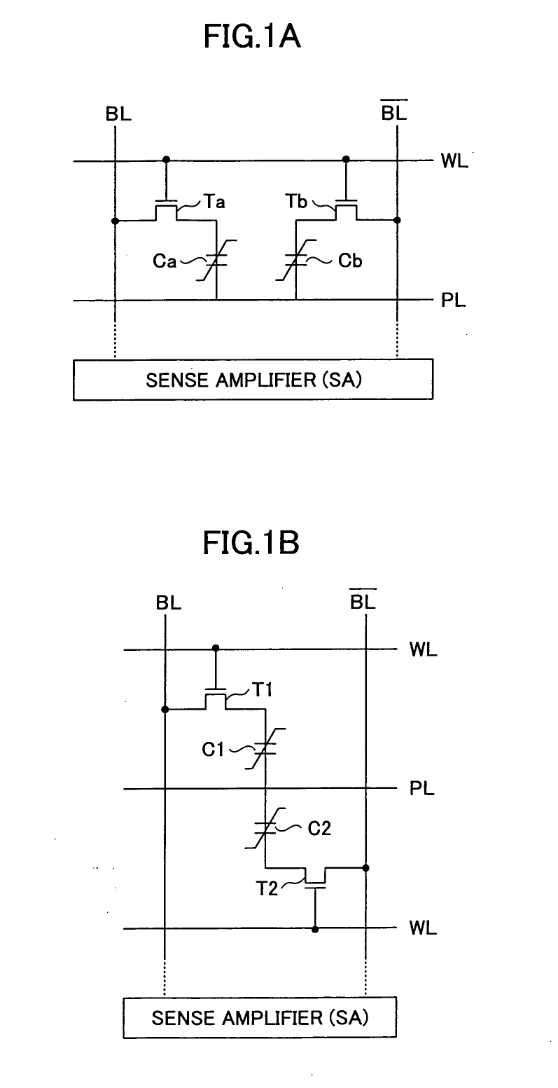

### DETAILED DESCRIPTION OF THE PREFERED EMBODIMENTS

The preferred embodiments of the present invention are described below with reference to the attached drawings. In the embodiment, a titanium aluminum nitride (TiAlN) film with superior oxygen blocking ability but inferior in crystal orientation is used as a barrier film inserted between a contact plug and the lower electrode of a ferroelectric capacitor, and a titanium (Ti) film is placed on the TiAlN film in order to improve the crystal orientation of the lower electrode and the ferroelectric film of the ferroelectric capacitor.

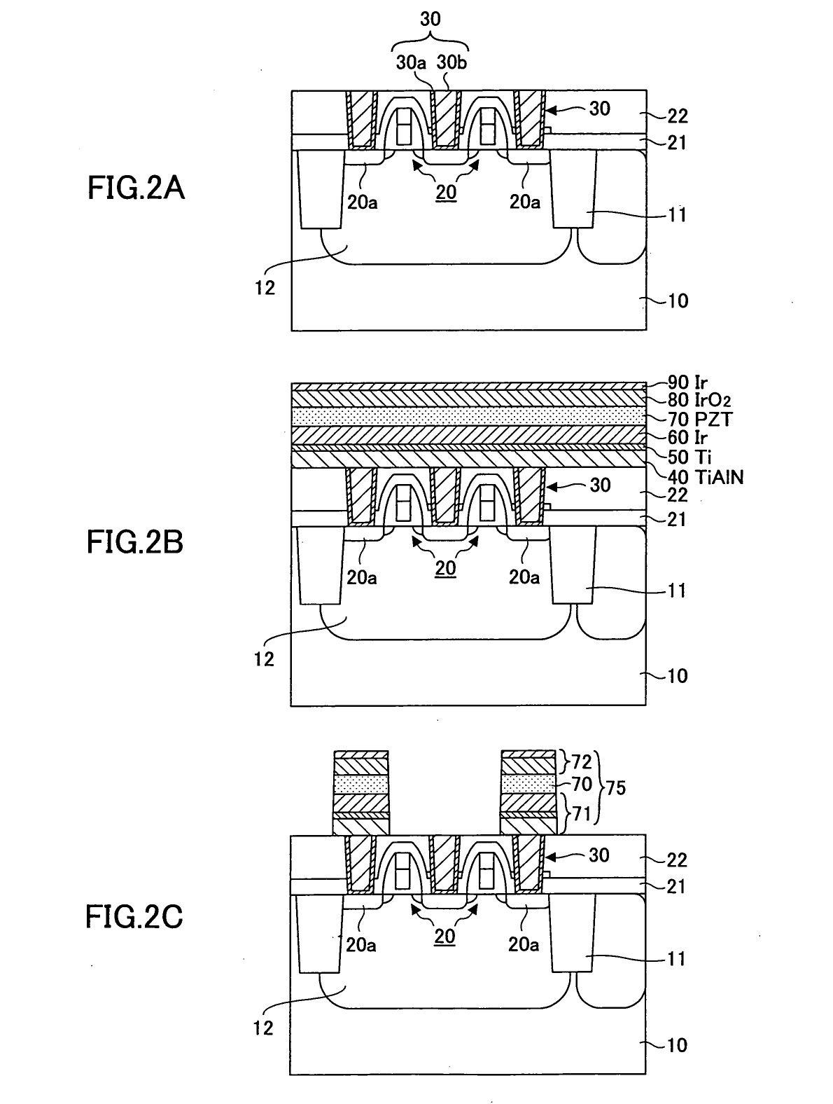

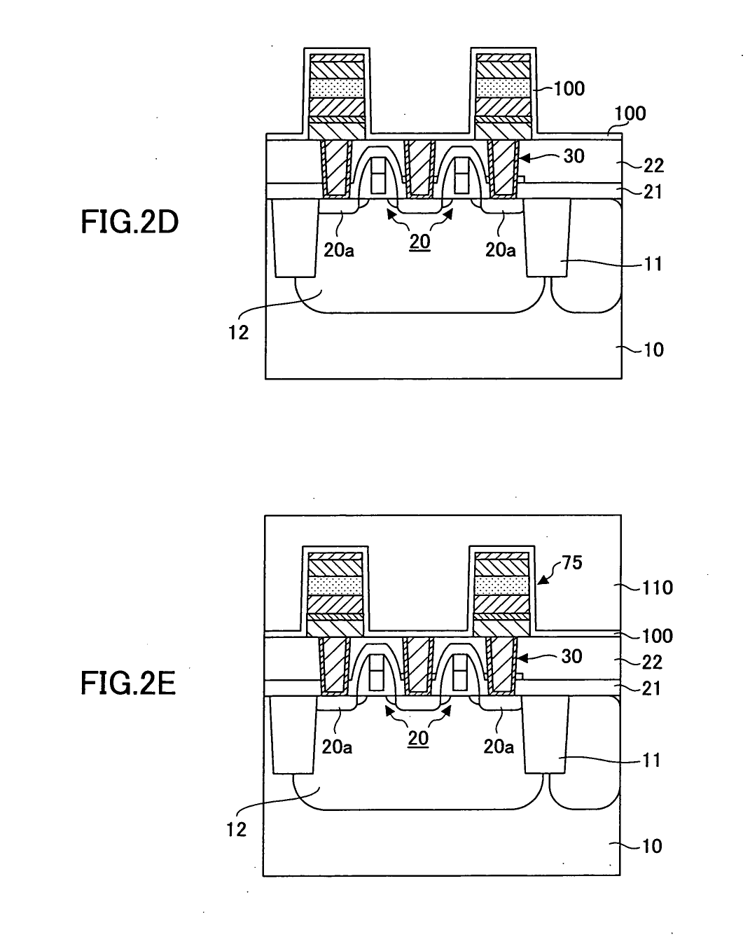

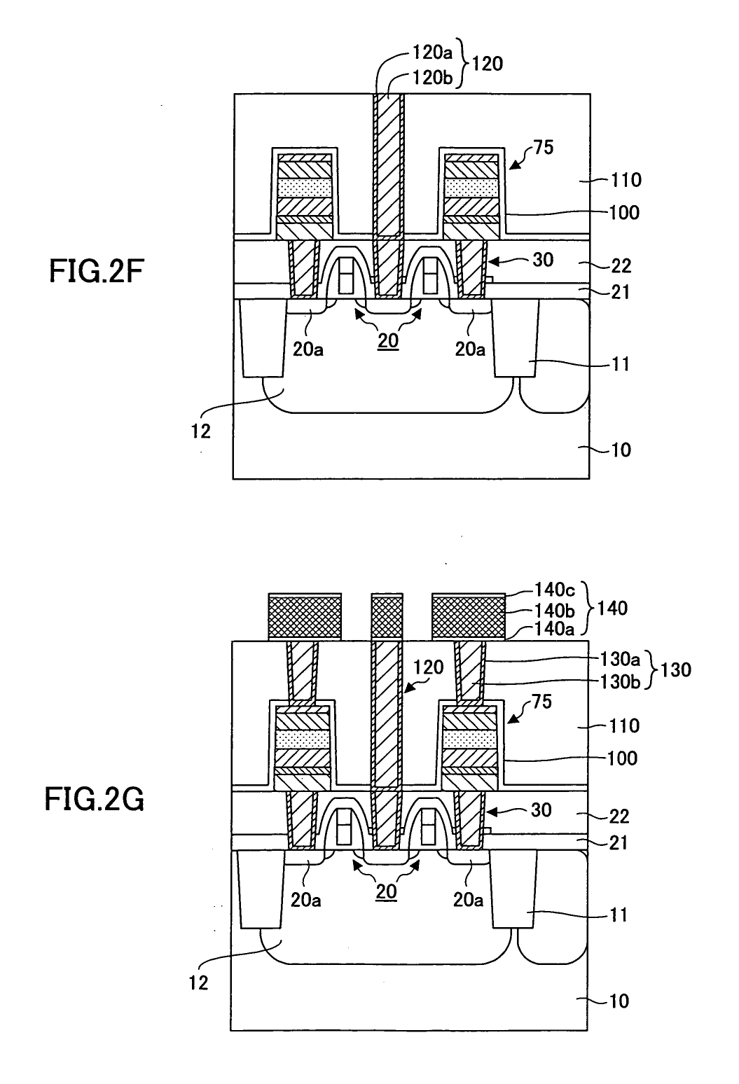

FIG. 2A through FIG. 2G illustrate in cross-sectional views a semiconductor device fabrication process according to an embodiment of the invention.

First, as illustrated in FIG. 2A, MOS transistors 20 are fabricated using a known technique in a well region 12 defined by active region isolation (e.g., STI region) 11 in a semiconductor substrate 10. The MOS transistors 20 are covered with a cover insulating film (e.g., SiON film) 21, and a first interlevel dielectric film 22 is deposited. Contact plugs 30 reaching the impurity diffusion regions 20a of the MOS transistors 20 are formed in the first interlevel dielectric film 22. The contact plug 30 is formed by, for example, sputtering a TiN (50 nm)/Ti (30 nm) glue film 30a in a contact hole (not shown) formed in the first interlevel dielectric film 22, depositing a tungsten (W) film 30b by CVD, and flattening the surface by CMP.

Then, as illustrated in FIG. 2B, a titanium aluminum nitride (TiAlN) film 40, a titanium (Ti) film 50, an iridium (Ir) film 60, a ferroelectric film 70, an iridium oxide (IrO2) film 80, and an iridium (Ir) film 90 are deposited successively in this order. The TiAlN film 40, Ti film 50, and Ir film 60 are used to form the lower electrode of a ferroelectric capacitor. The IrO2 film 80 and the Ir film 90 are used to form the upper electrode of the ferroelectric capacitor. To be more precise, the TiAlN film 40 with a thickness of 100 nm, which functions as an oxygen barrier film, is formed, and then, the Ti film 50 with thickness of 20 nm is formed as a seed film for improving the crystal orientation of the upper films. The Ir film 60 with a thickness of 100 nm, which serves as a lower electrode film, is formed over the Ti film 50 by sputtering.

The ferroelectric film 70 is formed by depositing a 5 nm first PZT film by MOCVD over the Ir film 60, and successively depositing a 115 nm second PZT film by MOCVD. The wafer temperature and the pressure during the MOCVD process are about 620° C. and 5 Torr, respectively. The first PZT film and the second PZT film have the same composition; however, the only difference is the partial pressure of oxygen during the film formation. The partial pressure of oxygen in forming the first PZT film is lower than that for the second PZT film because the crystal quality of the PZT Film is more improved at a lower partial pressure of oxygen. However, if the entire PZT film is formed at a lower partial pressure of the oxygen gas, oxygen deficiency in the PZT film becomes conspicuous, which causes leakage current to increase. Accordingly, two-step film formation is employed in the embodiment to form the PZT ferroelectric film 70 with satisfactory film quality.

The IrO2 film 80 with a thickness of 150 nm, which serves as an upper electrode film, is formed over the PZT film, and then the Ir film 90 with a thickness of 50 nm is formed.

Then, as illustrated in FIG. 2C, the above-described films 40, 50, 60, 70, 80, and 90 are patterned into a stacked ferroelectric capacitor 75 consisting of an upper electrode 72, a ferroelectric film 70, and a lower electrode 71 using known patterning and etching techniques. For the ferroelectric film 70 to recover from the damage suffered during the film formation of the upper electrode 72, recovery annealing is performed in the annealing furnace at 550° C. for 60 minutes in the oxygen (O₂) atmosphere.

Then, as illustrated in FIG. 2D, the ferroelectric capacitor 75 and the first interlevel dielectric film 22 are covered with a protection film 100 with a thickness of 20 nm by an atomic layer deposition (ALD) method. In this example, the protection film 100 is an aluminum oxide film with excellent step coverage.

Then, as illustrated in FIG. 2E, the second interlevel dielectric film 110 is deposited over the entire surface, and flattened by CMP. In this example, the second interlevel dielectric film 110 is an oxide film formed by a high density plasma (HDP) CVD apparatus. The net thickness of the second interlevel dielectric film 110 after CMP is 300 nm above the upper electrode 72 of the ferroelectric capacitor 75.

Then, as illustrated in FIG. 2F, a tungsten (W) plug 120 connected to the underlayer W plug 30 is formed in the second interlevel dielectric film 110. To be more precise, a contact hole (not shown) reaching the W plug 30 is formed in the second interlevel dielectric film 110, a glue film 120a and a tungsten film 120b are formed in the contact hole and over the second interlevel dielectric film 110, and CMP is performed. The glue film 120a is, for example, a titanium nitride (TiN) film with a thickness of 50 nm. The W plug 120 and the underlayer W plug 30 provide via-to-via contact, and electric contact from an upper-layer metal interconnection (which will be described below) to the substrate 10 is achieved.

Then, as illustrated in FIG. 2G, a tungsten (W) plug connected to the upper electrode 72 of the ferroelectric capacitor 75 is formed. To be more precise, an antioxidizing protection film (not shown) with thickness of 100 nm is formed of SiON to protect the exposed surface of tungsten (W) plug 120, and a contact hole (not shown) reaching the upper electrode Ir layer 90 of the ferroelectric capacitor 75 is formed in the second interlevel dielectric film 110. Then, recovery annealing (O₂ furnace annealing) is performed at 500° C. for 60 minutes, and the SiON antioxidizing protection film is etched back. A TiN glue film 130a and tungsten (W) film 130b are deposited in the contact hole and over the entire surface of the second interlevel dielectric film 110, and the glue film 130a and the tungsten film 130b deposited over the second interlevel dielectric film 110 surface are removed by CMP to define the tungsten plug 130.

In addition, a first metal interconnection 140 is formed over the second interlevel dielectric film 110. In this example, a TiN (70 nm) film 140a, an Al—Cu (360 nm) film 140b, and a TiN (50 nm) film 140c are successively deposited, and patterned into a prescribed shape to form the metal interconnection 140. Although not shown in the figure, the second and subsequent metal interconnections and contact plugs for connecting metal connections at different layers may be formed, and finally, a SiN cover film is formed to protect the semiconductor device.

In this semiconductor device with the ferroelectric capacitor 75, the titanium (Ti) seed layer 50 capable of improving the crystal orientation of the upper layers is arranged on the TiAlN film 40 that serves as the oxygen barrier layer in the lower electrode 71. The Ti seed film 50 with strong self-orientation allows the iridium (Ir) electrode film 60 to grow with its orientation kept in good condition, and as a result, the crystal orientation of the ferroelectric film 70 formed on the Ir electrode film 60 is also improved.

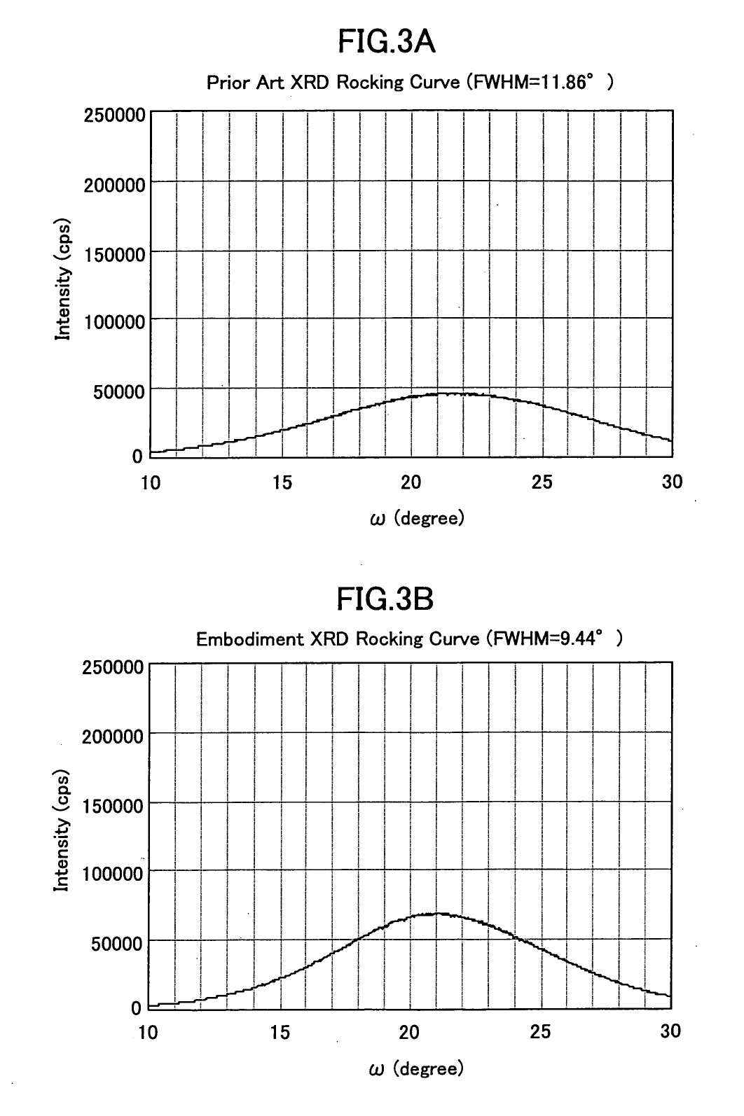

FIG. 3A and FIG. 3B are graphs of X-ray diffraction (XRD) measurement results showing advantageous effect of the semiconductor device of the embodiment, as compared with the conventional device. To be more precise, FIG. 3A is an XRD rocking curve of the iridium (Ir) film arranged directly on the TiAlN film formed on a thermally oxidized film, without inserting a titanium (Ti) film, as in the conventional technique. FIG. 3B is an XRD rocking curve of the iridium (Ir) film 60 formed over the TiAlN film 40 via a Ti film 50 inserted between them according to the embodiment.

The sample wafers are fabricated under the same process conditions, except for the presence or the absence of the titanium (Ti) film 50 on the TiAlN film 40, and the Ir (111) peaks are observed on both sample wafers using an X-ray diffraction method to check the crystal qualities of the Ir films. These Ir (111) peaks are obtained by the rocking curve measurement only at the center of the wafers, and FWHM (Full Width at Half Maximum) values are determined. The smaller the FWHM value, the better the crystal orientation.

In the sample fabricated using the conventional method shown in FIG. 3A, the peak is flattened, and the FWHM value is about 12. In contrast, the sample fabricated according to the invention shows increased Ir (111) peak integrated intensity, and the FWHM value is less than 10, which is smaller then the conventional value by more than 2 degrees. This means that the crystal orientation of the Ir film 60 is improved by the existence of the underlying Ti film 50.

In conclusion, according to the embodiment, the crystal quality of the iridium (Ir) lower electrode film is improved even if a titanium aluminum nitride (TiAlN) film is used as an oxygen barrier film in a stacked FeRAM, and the crystal quality of the ferroelectric film (PZT film) placed directly over the Ir film is also improved. Consequently, a ferroelectric capacitor with high switching capacitance Qsw and high operational reliability can be achieved.

What is claimed is:

1. A semiconductor device with a ferroelectric capacitor, wherein a lower electrode of the ferroelectric capacitor includes an electrode film formed over a titanium aluminum nitride (TiAlN) film provided on a conductive plug for connecting the ferroelectric capacitor to an active element, via a titanium (Ti) film inserted between the electrode film and the TiAlN film.

2. The semiconductor device of claim 1, wherein the electrode film of the lower electrode is made of iridium (Ir).

3. The semiconductor device of claim 1, wherein the ferroelectric capacitor includes a PZT ferroelectric film positioned on the electrode film of the lower electrode.

4. The semiconductor device of claim 1, wherein the TiAlN film has an island pattern that covers the top face of the conductive plug and the surrounding area.

5. The semiconductor device of claim 1, wherein the electrode film of the lower electrode formed over the titanium film has an FWHM (Full Width at Half Maximum) value less than 10°.

6. The semiconductor device of claim 1, wherein the conductive plug is a tungsten plug.

7. A semiconductor device fabrication method comprising the steps of:
forming a conductive plug in an insulating film so as to be connected to an element on a semiconductor substrate;
forming a titanium aluminum nitride (TiAlN) oxygen barrier film over the conductive plug;
forming a titanium (Ti) seed film over the oxygen barrier film; and
forming a lower electrode film of a ferroelectric capacitor over the titanium seed film.

8. The semiconductor device fabrication method of claim 7, wherein the lower electrode film is formed of iridium (Ir).

9. The semiconductor device fabrication method of claim 7, further comprising the step of:
forming a PZT ferroelectric film over the lower electrode film.

10. The semiconductor device fabrication method of claim 7, further comprising the step of:
forming a ferroelectric film over the lower electrode film by an MOCVD method.

11. The semiconductor device fabrication method of claim 9 or 10, further comprising the steps of:
forming an upper electrode film over the ferroelectric film; and
patterning the upper electrode film, the ferroelectric film, the lower electrode film, the titanium (Ti) seed film and the oxygen barrier film into a prescribed shape to form the ferroelectric capacitor.

12. The semiconductor device fabrication method of claim 11, further comprising the step of:
performing recovery annealing after the patterning of the ferroelectric capacitor.

13. The semiconductor device fabrication method of claim 7, wherein the conductive plug is made of tungsten.
